(19) United States
(12) Patent Application Publication
(10) Pub. No.: US 2025/0351707 A1
(43) Pub. Date: Nov. 13, 2025

(54) DISPLAY PANEL AND METHOD FOR MAKING THE SAME, AND DISPLAY DEVICE

(71) Applicant: HKC CORPORATION LIMITED, SHENZHEN (CN)

(72) Inventors: Yangling TANG, SHENZHEN (CN); Zhisheng XIE, SHENZHEN (CN); Qin LIANG, SHENZHEN (CN); Xiufeng ZHOU, SHENZHEN (CN); Haijiang YUAN, SHENZHEN (CN)

(21) Appl. No.: 19/194,089

(22) Filed: Apr. 30, 2025

(30) Foreign Application Priority Data
May 10, 2024 (CN) 202410572303.4

(51) Int. Cl. H10K 59/80

(52) U.S. Cl. CPC H10K 59/873

(57) ABSTRACT

A display panel, a method for making the display panel, and a display device are provided. The display panel includes a substrate, a plurality of sub-pixels, a plurality of pixel limiting layers, a plurality of isolation structures, an encapsulation layer, and a protective layer. Each of the plurality of isolation structures includes a main body and an overhang. The encapsulation layer is disposed a surface of each of the plurality of sub-pixels away from the substrate. In response to parts of the encapsulation layer being disposed on a side of the overhang away from the main body, the parts of the encapsulation layer and the overhang define gap spaces. A width of each gap space along a set direction is less than or equal to 4 μm, and the set direction is a direction parallel to a line connecting two sub-pixels adjacent to the overhang.

### CROSS-REFERENCE TO RELATED APPLICATIONS

The present application claims priority to Chinese Patent Application No. 202410572303.4, filed May 10, 2024, which is herein incorporated by reference in its entirety.

### TECHNICAL FIELD

The present disclosure relates to the field of display technology, and in particular to a display panel, a method for making the display panel, and a display device.

### BACKGROUND

Compared with traditional rigid display panels, flexible organic light-emitting diode (OLED) display panels have advantages, such as self-luminescence, wide viewing angle, high contrast, low power consumption, and extremely high response speed, etc. OLED luminescent material is an organic material that is extremely sensitive to water and oxygen. Usually, an encapsulation layer is used to encapsulate a display panel, so as to ensure the normal operation of the OLED luminescent material. Due to the presence of an overhang structure in the display panel, during the preparation of sub-pixels, an organic light-emitting layer may be formed above the overhang structure. Therefore, in the subsequent encapsulating process, such as during individually encapsulating the sub-pixels, an undercut gap may be formed between the encapsulation layer structure and the overhang structure. Furthermore, due to the different etching methods used in different structures, the liquid may remain in the undercut gap, so that the display panel may be corroded by water vapor, which may affect service life of the display panel and cause the reliability of the display panel to deteriorate.

### SUMMARY OF THE DISCLOSURE

The present disclosure provides a display panel. The display panel includes a substrate, a plurality of sub-pixels disposed on the substrate, a plurality of pixel limiting layers disposed on the substrate and configured to limit positions of the plurality of subpixels, a plurality of isolation structures, an encapsulation layer, and a protective layer. Each of the plurality of isolation structures includes a main body and an overhang, the main body is disposed on a surface of a corresponding one of the plurality of pixel defining layers away from the substrate, and the overhang is disposed on a surface of the main body away from the corresponding one of the plurality of pixel defining layers. The encapsulation layer is disposed a surface of each of the plurality of sub-pixels away from the substrate. In response to parts of the encapsulation layer being disposed on a side of the overhang away from the main body, the parts of the encapsulation layer and the overhang define gap spaces; a width of each gap space along a set direction is less than or equal to 4 μm, and the set direction is a direction parallel to a line connecting two sub-pixels adjacent to the overhang. The protective layer is disposed on a side of the encapsulation layer away from the substrate and the side of the overhang away from the substrate.

In some embodiments, each of the plurality of sub-pixels includes an anode layer, a first light-emitting layer, and a cathode layer stacked in sequence. The display panel further includes a second light-emitting layer, the second light-emitting layer is disposed on a surface of the overhang away from the main body, and the second light-emitting layer is close to an edge of the overhang. The parts of the encapsulation layer are disposed on a surface of the second light-emitting layer away from the overhang, and the parts of the encapsulation layer extend out of the second light-emitting layer toward another adjacent sub-pixel, so that the gap spaces are formed between the overhang, the second light-emitting layer, and the encapsulation layer.

In some embodiments, the first light-emitting layer and the second light-emitting layer are formed by the same deposition process.

In some embodiments, the encapsulation layer is not disposed on the side of the overhang away from the main body.

In some embodiments, a surface of the encapsulation layer away from the substrate is flush with a surface of the overhang away from the main body.

The present disclosure further provides a method for making the display panel. The method includes the following operations:
providing a substrate;
forming a plurality of anode layers on the substrate;
forming a plurality of pixel defining layers, a plurality of main bodies, and a plurality of overhangs in sequence on the substrate, wherein the plurality of pixel defining layers are configured to define positions of a plurality of sub-pixels, and the plurality of main bodies and the plurality of overhangs form a plurality of isolation structures;
forming a first light emitting layer on a surface of each anode layer away from the substrate;
forming a cathode layer on a surface of the first light emitting layer away from a corresponding one of the plurality of anode layers;
forming an encapsulation layer on a surface of the cathode layer away from the substrate, wherein in response to parts of the encapsulation layer being disposed on a side of the overhang away from the main body, the parts of the encapsulation layer and the overhang define gap spaces;
removing a part of the encapsulation layer, so that a width of each gap space along a set direction is less than or equal to 4 μm, wherein the set direction is a direction parallel to a line connecting two sub-pixels adjacent to the overhang; and
forming a protection layer on a surface of the encapsulation layer away from the substrate and a surface of the overhang away from the substrate.

In some embodiments, the forming a first light emitting layer on a surface of each anode layer away from the substrate, includes: forming the first light emitting layer on the surface of each anode layer away from the substrate and forming second light-emitting layers on the surface of the overhang away from the main body. The forming an encapsulation layer on a surface of the cathode layer away from the substrate, wherein in response to parts of the encapsulation layer being disposed on a side of the overhang away from the main body, the parts of the encapsulation layer and the overhang define gap spaces, includes: forming the encapsulation layer on the surface of the cathode layer away from the substrate, wherein the parts of the encapsulation layer are disposed the surface of the second light-emitting layer away from the overhang and extends out of the second light-emitting layer toward another adjacent sub-pixel, so that the gap space is formed between the overhang, each second light-emitting layer, and the encapsulation layer.

In some embodiments, the removing a part of the encapsulation layer, so that a width of each gap space along a set direction is less than or equal to 4 μm, includes: removing the parts of the encapsulation layer, and removing the second light-emitting layers, so that the encapsulation layer and the second light-emitting layers do not exist on the side of the overhang away from the main body.

In some embodiments, after removing the parts of the encapsulation layer and removing the second light-emitting layers, the method further includes: flattening the encapsulation layer.

The present disclosure further provides a display device. The display device includes the display panel and a power supply configured for supplying power to the display panel. The display panel is the display panel as described in any one of the above embodiments, or the display panel is formed by using the method described in any one of the above embodiments.

### BRIEF DESCRIPTION OF THE DRAWINGS

In order to more clearly illustrate the technical solutions in some embodiments of the present disclosure, hereinafter, a brief introduction will be given to the accompanying drawings that are used in the description of some embodiments. Obviously, the accompanying drawings in the description below are merely some embodiments of the present disclosure. For those of ordinary skill in the art, other accompanying drawings may be obtained based on these accompanying drawings without any creative efforts.

FIG. 1 is a structural schematic view of a display panel in some embodiments of the present disclosure.

FIG. 2 is a structural schematic view of the display panel before structural processing in some embodiments of the present disclosure.

FIG. 3 is a structural schematic view of the display panel in some embodiments of the present disclosure.

FIG. 4 is a structural schematic view of the display panel in some embodiments of the present disclosure.

FIG. 5 is a structural schematic view of the display panel in some embodiments of the present disclosure.

FIG. 6 is a schematic flow chart illustrating a method for making the display panel in some embodiments of the present disclosure.

FIG. 7 is a structural schematic view of a display device in some embodiments of the present disclosure.

### DETAILED DESCRIPTION

The technical solutions in some embodiments of the present disclosure may be clearly and completely described in conjunction with accompanying drawings in some embodiments of the present disclosure. It should be understood that the specific embodiments described herein are only for explaining the present disclosure and are not intended to limit the present disclosure. It should also be noted that, in order to facilitate the description of the present disclosure, only some, but not all, structures related to the present disclosure are shown in the drawings. Based on the embodiments in the present disclosure, all other embodiments obtained by those of ordinary skill in the art without any creative efforts are in the protection scope of the present disclosure.

The terms “first”, “second”, or the like in the present disclosure are used to distinguish different objects, rather than to describe a specific order. In addition, the terms “including”, “comprising”, and “having”, as well as any variations of the terms “including”, “comprising”, and “having”, are intended to cover non-exclusive inclusions. For example, a process, method, system, product, or device that includes a series of operations or units is not limited to the listed operations or units, but optionally includes operations or units that are not listed, or optionally includes other operations or units that are inherent to these processes, methods, products, or devices.

The reference to “embodiments” in the present disclosure means that, specific features, structures, or characteristics described in conjunction with some embodiments may be included in at least one embodiment of the present disclosure. The phrase appearing in various positions in the specification does not necessarily refer to the same embodiment, nor is it an independent or alternative embodiment that is mutually exclusive with other embodiments. Those of ordinary skill in the art explicitly and implicitly understand that the embodiments described in the present disclosure can be combined with other embodiments.

A main purpose of the present disclosure is to provide a display panel, a method for making the display panel, and a display device, so as to solve the problems of undercut gap and sealing during manufacturing the display panel in related art.

A display panel manufacturing method in related art adopts a conventional maskless process. A mask process is used in a semiconductor manufacturing method, and many steps involve photolithography technology. A pattern film used in these steps is called a mask. A function of the mask is to cover an opaque pattern template in a selected area on a silicon wafer, so that subsequent corrosion or diffusion may only affect areas outside the selected area. In the above process, a single sub-pixel needs to be evaporated and encapsulated. That is, after a first pixel film layer is evaporated and encapsulated, a first pixel evaporation layer and an encapsulating film layer, except for a first pixel area, are removed. That is, only the evaporation and encapsulating in the first pixel area remain to form a first pixel. Similarly, after a second pixel film layer is evaporated and encapsulated, a second pixel evaporation layer and the encapsulating film layer, except for a second pixel area, are removed. That is, only the evaporation and encapsulating in the second pixel area remain to form a second pixel. Similarly, after a third pixel film layer is evaporated and encapsulated, a third pixel evaporation layer and the encapsulating film layer, except for a third pixel area, are removed. That is, only the evaporation and encapsulating in the third pixel area remain to form a third pixel. In the process flow, an overhang structure is configured to isolate, seal, and protect individual pixel units, so as to avoid light pollution between the sub-pixels, and crosstalk between the sub-pixels, etc. The display panel includes the overhang structure. During the evaporation process of the sub-pixels of the display panel, a light-emitting layer may be partially disposed on the overhang structure, leaving residues on the overhang structure. Therefore, in subsequent encapsulating and removal of the evaporation layer and the encapsulation layer of other display areas process, an undercut gap structure may be formed between the upper evaporation layer, the middle light-emitting layer, and the lower overhang structure. Moreover, the etching processes for different structures and materials are different. For example, dry etching is used for CVD encapsulation film layer, while wet etching is used for the evaporation layer of OLED. Therefore, residual liquid may remain in a gap of the undercut gap structure, which is difficult to remove. Therefore, in the subsequent reliability verification, water vapor may enter and corrode through the gap, resulting in a shorter water vapor infiltration path and poor reliability, thereby affecting production quality and service life of the display panel.

Therefore, the present disclosure provides a display panel, a method for making the display panel, and a display device. In the present disclosure, process operations are added in the process flow, so as to remove corresponding partial structures, thereby reducing or eliminating the undercut gap structure. Therefore, the above-mentioned problem may be solved.

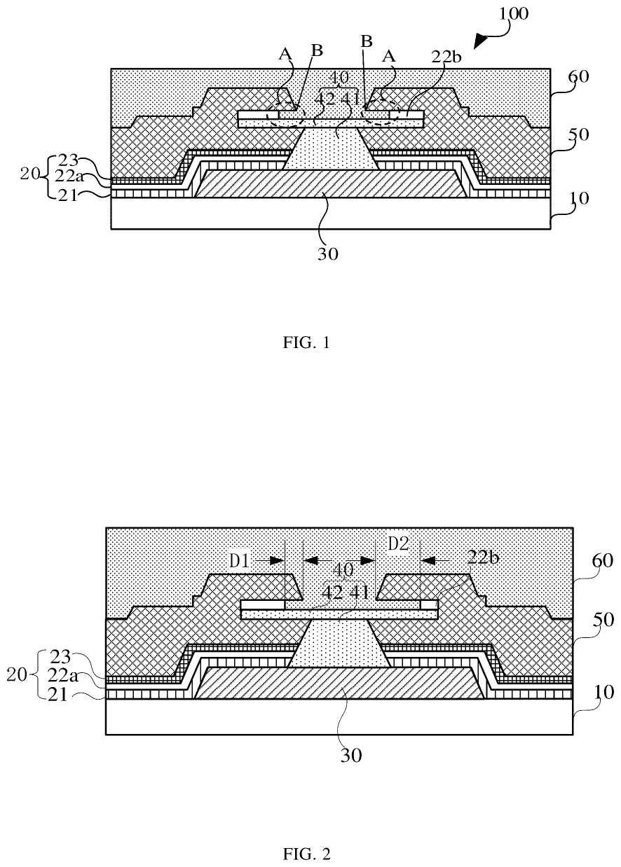

As illustrated in FIG. 1, FIG. 1 is a structural schematic view of a display panel in some embodiments of the present disclosure. A display panel 100 includes a substrate 10, a plurality of sub-pixels 20, a plurality of pixel defining layers 30, a plurality of isolation structures 40, and an encapsulation layer 50. The plurality of sub-pixels 20 are disposed on the substrate 10. The plurality of pixel defining layers 30 are disposed on the substrate 10 and configured to define positions of the plurality of sub-pixels 20. Each isolation structure 40 includes a main body 41 and an overhang 42, and the main body 41 is disposed on a surface of a corresponding pixel defining layer 30 away from the substrate 10. The overhang 42 is disposed on a surface of the main body 41 away from the corresponding pixel defining layer 30. The encapsulation layer 50 is disposed on a surface of each sub-pixel 20 away from the substrate 10. Parts of the encapsulation layer 50 are disposed on a side of the overhang 42 away from the main body 41. The encapsulation layer 50 includes edges B, each edge B is disposed on the side of the overhang 42 away from the main body 41, and each edge B is close to the sub-pixel 20 adjacent to the encapsulation layer 50. Each edge B and the overhang 42 define a gap space A. That is, gap spaces A are formed between the overhang 42 and the encapsulation layer 50. A width of the gap space A along a set direction is less than or equal to 4 μm, and the set direction is a direction parallel to a line connecting two sub-pixels 20 adjacent to the overhang 42. A protective layer 60 is disposed on a side of the encapsulation layer 50 away from the substrate 10 and a side of the overhang 42 away from the substrate 10, and the protective layer 60 covers the encapsulation layer 50 and the overhang 42.

Since different sub-pixels 20 are completed separately, the number of etching cycles experienced by different sub-pixels 20 is different, so that the gap space A is formed between the overhang 42 and the encapsulation layer 50, and the widths of a plurality of gap spaces A along the set direction are different. The more the etching cycles, the wider the width of the gap space A along the set direction. As illustrated in FIG. 2, FIG. 2 is a structural schematic view of the display panel before structural processing in some embodiments of the present disclosure. For two adjacent sub-pixels 20, the number of etching experienced by a left sub-pixel 20 is less than the number of etching experienced by a right sub-pixel 20, so that a width D1 of a left gap space A along the set direction is less than a width D2 of a right gap space A along the set direction.

The substrate 10 plays a role in supporting entire panel of the display panel 100. The substrate 10 includes a rigid substrate 10 and a flexible substrate 10. The rigid substrate 10 is usually made of rigid materials, such as glass, plastic, or the like. The rigid substrate 10 has good stability and durability, and is suitable for large-size display screens and professional displays. The flexible substrate 10 is usually made of flexible material, such as plastic, metal foil, or the like. The flexible substrate 10 is suitable for flexible displays and wearable devices. The quality and the performance of the substrate 10 directly affect the display effect and the service life of the display. Therefore, when manufacturing and selecting the display panel 100, the selection of the substrate 10 is particularly important. A material for encapsulating the substrate 10 may include a rigid material and a flexible material. The material for encapsulating the substrate 10, includes, but is not limited to, a BT material, an ABF material, a MIS material, a PI (polyimide) and PE (polyester) resin, or the like, or their combinations.

The plurality of pixel defining layers 30 are configured to define or limit positions of the plurality of sub-pixels 20 of the display panel 100, so as to avoid interference between colors. A material of each pixel defining layer 30 may be an organic material, an organic material with an inorganic coating, or an inorganic material. The organic material of each pixel defining layer 30 includes, but is not limited to, polyimide. The inorganic material of each pixel defining layer 30 includes, but is not limited to, silicon oxide (SiO₂), silicon nitride (Si₃N₄), silicon oxynitride (Si₂N₂O), magnesium fluoride (MgF₂), or their combinations.

Each isolation structure 40 includes the main body 41 and the overhang 42, and the main body 41 is disposed on the surface of the corresponding pixel defining layer 30 away from the substrate 10. The overhang 42 is disposed on the surface of the main body 41 away from the corresponding pixel defining layer 30. The isolation structure 40 separates adjacent sub-pixels 20, so as to prevent cathodes of the adjacent sub-pixels 20 from conducting and avoid color interference between the adjacent sub-pixels 20, thereby better solving the problems of low resolution and low yield of the display panel and the display device. A material of the main body 41 may be a conductive material, such as, a metal, metal oxide, or the like. In some embodiments, the material of the main body 41 may include, but not limited to, aluminum (Al), magnesium (Mg), copper (Cu), silver (Ag), indium tin oxide (ITO), indium zinc oxide (IGZO), other conductive metals, other metal oxides, or their combinations. That is, the material of the main body 41 is not limited, as long as the material of the main body 41 meets use conditions of an implementation solution. A material of the overhang 42 may be an insulating material, such as silicon monoxide (SiO), silicon dioxide (SiO₂), silicon nitride (SiNx), silicon oxynitride (SiNO), or the like.

In some embodiments, each sub-pixel 20 includes an anode layer 21, a first light-emitting layer 22a, and a cathode layer 23 stacked in sequence. The display panel 100 further includes a second light-emitting layer 22b. The second light-emitting layer 22b is disposed on a surface of the overhang 42 away from the main body 41, and the second light-emitting layer 22b is close to an edge of the overhang 42. A part of the encapsulation layer 50 is disposed on a surface of the second light-emitting layer 22b away from the overhang 42, and the part of the encapsulation layer 50 extends out of the second light-emitting layer 22b toward another adjacent sub-pixel 20. Therefore, the gap space A is formed between the overhang 42, the second light-emitting layer 22b, and the encapsulation layer 50.

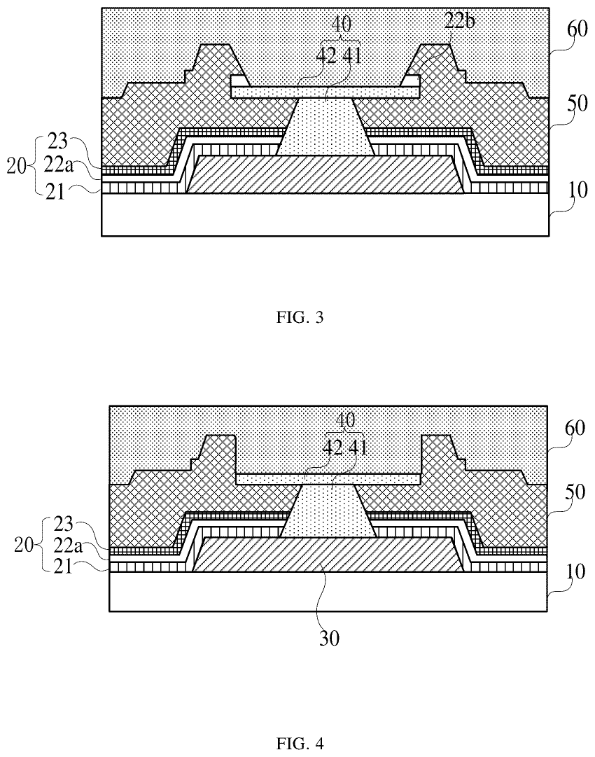

As illustrated in FIG. 3, FIG. 3 is a structural schematic view of the display panel in some embodiments of the present disclosure. As illustrated in FIG. 3, the encapsulation layer 50 is in direct contact with the second light-emitting layer 22b, and the second light-emitting layer 22b and the encapsulation layer 50 are disposed on the overhang 42 or above the overhang 42. However, there is no gap space A between the second light-emitting layer 22b, the encapsulation layer 50, and the overhang 42. The structure as shown in FIG. 3 eliminates the gap space A, therefore, in the subsequent etching process, the water vapor erosion and other problems caused by the different etching processes may not affect the reliability and the service life of the display panel 100.

A material of the anode layer 21 primarily serves as the anode of the device, and a work function of the material of the anode layer 21 is required to be as high as possible, so as to improve hole injection efficiency. The material of the anode layer 21 may be the conductive material, such as chromium, titanium, gold, silver, copper, aluminum, ITO, or their combination, etc.

A material of the cathode layer 23 primarily serves as the cathode of the device. The lower the metal work function of the material of the cathode layer 23, the easier it is to inject electrons, which results in higher luminous efficiency. It also leads to reduced Joule heat generation during operation, and may significantly improve the service life of the device. The material of the cathode layer 23 may be the conductive material, such as chromium, titanium, gold, silver, copper, aluminum, ITO, or their combination, etc. The material of the cathode layer 23 and the material of the anode layer 21 may be the same material or different materials, which are selected according to actual needs.

The first light-emitting layer 22a and the second light-emitting layer 22b may include one or more of a hole injection layer (HIL), a hole transfer layer (HTL), an emitting layer (EML), and an electron transfer layer (ETL). A material of each of the first light-emitting layer 22a and the second light-emitting layer 22b may be an organic light-emitting material, such as a polymer, a small molecule organic compound, or a complex light-emitting material. The polymer is usually a conductive conjugated polymer or a semiconductor conjugated polymer. The polymer can be used to form films by spin coating, and the production is simple and the cost is low. However, the purity of the polymer is not easy to improve. The durability, brightness and color of the polymer are inferior to those of the small molecule organic compound. The small molecule organic light-emitting material is mainly an organic dye. The small molecule organic light-emitting material has the advantages of strong chemical modification, wide selection range, easy purification, and high quantum efficiency, etc. The small molecule organic light-emitting material may produce various color emission peaks, such as red, green, blue, and yellow, etc. However, most of the small molecule organic light-emitting material suffer from concentration quenching and other problems in a solid state. The performance of the complex light-emitting material is between that of the organic material and that of the inorganic material. The complex light-emitting material has both high fluorescence quantum efficiency of the organic material and high stability of the inorganic material. Therefore, the complex light-emitting material is regarded as the light-emitting material with great application prospects.

In some embodiments, the first light-emitting layer 22a and the second light-emitting layer 22b are formed by using the same deposition process. The overhang 42 of the isolation structure 40 extends out of the main body 41. Therefore, in the production process of the light-emitting layer of the display panel 100, a part of the light-emitting layer is disposed on the anode layer 21 and stacked with the anode layer 21, so as to form the first light-emitting layer 22A. The other part of the light-emitting layer is disposed on a part of the overhang 42 that extends out of the main body 41, so as to form the second light-emitting layer 22B.

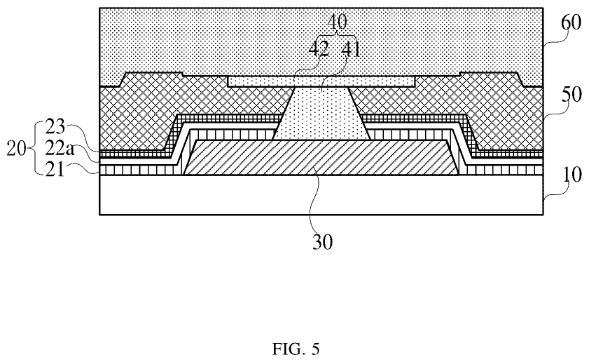

In some embodiments, as illustrated in FIG. 4 and FIG. 5, FIG. 4 is a structural schematic view of the display panel in some embodiments of the present disclosure, and FIG. 5 is a structural schematic view of the display panel in some embodiments of the present disclosure. As illustrated in FIG. 4 and FIG. 5, the encapsulation layer 50 is not disposed on the side of the overhang 42 away from the main body 41. By adding a process operation in the manufacturing process, the second light-emitting layer 22b and the encapsulation layer 50 above the overhang 42 are removed, so that the surface of the overhang 42 away from the main body 41 is exposed. As illustrated in FIG. 4, the encapsulation layers 50 on two opposite sides (a left side and a right side) of the overhang 42 remain, and only the second light-emitting layer 22b and the encapsulation layer 50 disposed on the surface of the overhang 42 away from the main body 41 are removed.

In some embodiments, as illustrated in FIG. 5, the surface of the encapsulation layer 50 away from the substrate 10 is flush with the surface of the overhang 42 away from the main body 41. The second light-emitting layer 22b and the encapsulation layer 50 above the overhang 42 are removed, and the encapsulation layers 50 on two opposite sides (the left side and the right side) of the overhang 42 are flattened, so that the surface of the encapsulation layer 50 away from the substrate 10 is flush with the surface of the overhang 42 away from the main body 41.

The protective layer 60 may further improve the sealing of the display panel 100, and the protective layer 60 is disposed on the surface of the encapsulation layer 50 away from the substrate 10 and the surface of the overhang 42 away from the substrate 10. After the sub-pixels 20 are encapsulated, the protective layer 60 is formed on the surface of the encapsulation layer 50 away from the substrate 10, so as to seal and protect the entire display panel 100. The encapsulation layer 50 and the protective layer 60 are mainly configured to protect and isolate each sub-pixel 20, and protect a structure of each sub-pixel 20, thereby preventing crosstalk between sub-pixels 20. The encapsulation layer 50 and the protective layer 60 isolate each sub-pixel 20 from the external environment, so as to prevent impurities, oxygen, moisture and other substances in the air from contaminating and corroding the display panel 100, and avoid damage to the display panel 100 by an external force. An encapsulation method includes, but is not limited to, a chemical vapor deposition (CVD) method, an atomic layer deposition technology (ALD), or a mixed barrier layer method, etc.

The traditional encapsulating technology is to encapsulate electrodes and organic functional layers on the rigid substrate 10. Generally, a cover plate and a desiccant are provided, and the substrate 10 and the cover plate are combined by a sealant, such as an epoxy resin. Thin-film encapsulation is currently the mainstream technology in the field of encapsulating. A thin film encapsulation material mainly includes an inorganic encapsulation material, an organic encapsulation material, and an inorganic-organic composite encapsulation material. The inorganic-organic composite encapsulation material has the advantages of good water and oxygen insulation of the inorganic encapsulation material and good film formation of the organic encapsulation material, so that the inorganic-organic composite encapsulation material becomes the mainstream choice in the field of encapsulation. A key and core material of the OLED device is an ultra-thin organic electroluminescent layer. The ultra-thin organic electroluminescent layer is extremely sensitive to water, oxygen and heat, which is the reason for the poor stability of the OLED device. Therefore, after the display panel 100 is made, the packaging layer 50 is provided to encapsulate the display panel 100, so as to protect the display panel 100 and prolong the service life of the display panel 100. In the display panel 100 of the present disclosure, the dense protective layer 60 is formed after forming the encapsulation layer 50, thereby further improving the sealing and the reliability of the display panel 100.

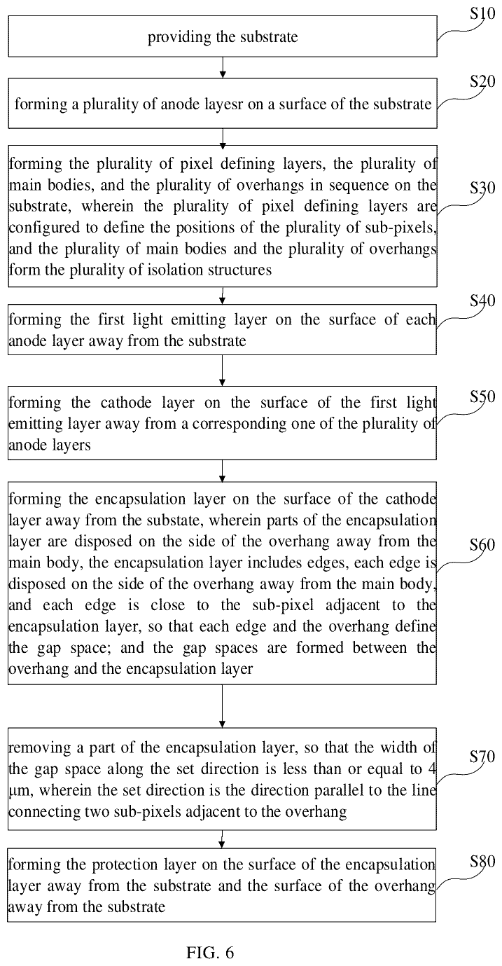

In order to solve the above problems, the present disclosure further provides a method for making the display panel 100. As illustrated in FIG. 6, FIG. 6 is a schematic flow chart illustrating a method for making the display panel in some embodiments of the present disclosure. In some embodiments, the method for making the display panel 100 includes the following operations.

In an operation S10: providing the substrate 10.

In an operation S20: forming a plurality of anode layers 21 on the surface of the substrate 10.

The materials of the substrate 10 and the anode layer 21 are the same as those in the above embodiments, which may not be described in detail here.

In an operation S30: forming the plurality of pixel defining layers 30, the plurality of main bodies 41, and the plurality of overhangs 42 in sequence on the substrate 10, wherein the plurality of pixel defining layers 30 are configured to define the positions of the plurality of sub-pixels 20, and the plurality of main bodies 41 and the plurality of overhangs 42 form the plurality of isolation structures 40.

The materials of the plurality of pixel defining layers 30, the plurality of main bodies 41, and the plurality of overhangs 42 are the same as those in the above embodiments, which may not be described in detail here.

In an operation S40: forming the first light emitting layer 22a on the surface of each anode layer 21 away from the substrate 10.

During the evaporation process, since the overhang 42 of the isolation structure 40 extends out of the main body 41 toward two opposite sides of the main body 41, parts of the light-emitting layer are disposed on protruding structures of the overhang 42 that extend out of the main body 41, so that the second light-emitting layer is formed.

In some embodiments, forming the first light emitting layer 22a on the surface of the anode layer 21 away from the substrate 10, includes: forming the first light emitting layer 22a on the surface of the anode layer 21 away from the substrate 10 and forming the second light-emitting layers 22b on the surface of the overhang 42 away from the main body 41.

In an operation S50: forming the cathode layer 23 on the surface of the first light emitting layer 22a away from a corresponding one of the plurality of the anode layers 21.

During the manufacturing process, when an angle of evaporation is not controlled, the partially overlapping cathode layer 23 may be formed on the surface of the second light-emitting layer 22b away from the overhang 42.

In an operation S60: forming the encapsulation layer 50 on the surface of the cathode layer 23 away from the substrate 10, wherein parts of the encapsulation layer 50 are disposed on the side of the overhang 42 away from the main body 41, the encapsulation layer 50 includes edges B, each edge B is disposed on the side of the overhang 42 away from the main body 41, and each edge B is close to the sub-pixel 20 adjacent to the encapsulation layer 50, so that each edge B and the overhang 42 define the gap space A; and the gap spaces A are formed between the overhang 42 and the encapsulation layer 50.

After the evaporation of the single sub-pixel 20 is completed, the encapsulation layer 50 is formed on the single sub-pixel 20. After forming the encapsulation layer 50 is completed, the evaporation structure on other sub-pixels 20 needs to be removed. That is, the encapsulation layer 50 and the sub-pixels 20 are etched. After the evaporation and encapsulation of one sub-pixel 20 are completed, the above operation is repeated to form other different sub-pixels 20 on the display panel 100, and the different sub-pixels 20 are separately encapsulated.

In some embodiments, the operations “disposing the parts of the encapsulation layer 50 on the side of the overhang 42 away from the main body 41, the encapsulation layer 50 including edges B that are disposed on the side of the overhang 42 away from the main body 41 and close to the sub-pixel 20 adjacent to the encapsulation layer 50, so that each edge B and the overhang 42 define the gap space A”, include the following operations: forming the encapsulation layer 50 on the surface of the cathode layer 23 away from the substrate 10, wherein the parts of the encapsulation layer 50 are disposed the surface of the second light-emitting layer 22b away from the overhang 42 and extends out of the second light-emitting layer 22b toward another adjacent sub-pixel 20, so that the gap space A is formed between the overhang 42, each second light-emitting layer 22b, and the encapsulation layer 50.

In an operation S70: removing a part of the encapsulation layer 50, so that the width of the gap space A along the set direction is less than or equal to 4 μm, wherein the set direction is the direction parallel to the line connecting two sub-pixels 20 adjacent to the overhang 42.

In the above structural embodiments, as illustrated in FIG. 3, treating the encapsulation layer 50 further includes: removing a part of the encapsulation layer 50, so that the width of the gap space A along the set direction is zero; or removing a part of the encapsulation layer 50 and a part of the second light-emitting layer 22b, so that the width of the gap space A along the set direction is zero. That is, in some embodiments, on the basis of the completed structure, a photolithography layer is formed on the surface of the encapsulation layer 50 away from the substrate 10, and the photolithography layer is patterned to retain the required structure. The photolithography layer and the encapsulation layer 50 are etched, so that the width of the gap space A along the set direction is less than or equal to 4 μm. Alternatively, the photolithography layer, the encapsulation layer 50, and the second light-emitting layer 22b are etched, so that the width of the gap space A along the set direction is less than or equal to 4 μm. The set direction is the direction parallel to the line connecting two sub-pixels 20 adjacent to the overhang 42.

In some embodiments, in step S70, removing the part of the encapsulation layer 50, so that the width of the gap space A along the set direction is less than or equal to 4 μm, includes: removing the part of the encapsulation layer 50, and removing the second light-emitting layer 22b, so that the encapsulation layer 50 and the second light-emitting layers 22b do not exist on the side of the overhang 42 away from the main body 41.

In some embodiments, after removing the part of the encapsulation layer 50 and removing the second light-emitting layer 22b, the method further includes: flattening the encapsulation layer 50. As illustrated in FIG. 5, in some embodiments, after removing the part of the encapsulation layer 50 and the second light-emitting layer 22b, flattening is performed on two opposite sides of the overhang structure, so as to remove the encapsulation layer 50 on the two opposite sides of the overhang structure.

In an operation S80: forming the protection layer 60 on the surface of the encapsulation layer 50 away from the substrate 10 and the surface of the overhang 42 away from the substrate 10.

As illustrated in FIG. 1, the protective layer 60 is formed after the individual sub-pixels 20 is encapsulated by the encapsulation layer 50. The entire display panel 100 is further encapsulated, so as to seal and protect the display panel 100. The encapsulation layer 50 and the protective layer 60 are mainly configured to protect and isolate each sub-pixel 20, and protect the structure of each sub-pixel 20, thereby preventing crosstalk between sub-pixels 20. The encapsulation layer 50 and the protective layer 60 isolate each sub-pixel 20 from the external environment, so as to prevent impurities, oxygen, moisture and other substances in the air from contaminating and corroding the display panel 100, and avoid damage to the display panel 100 by the external force. The encapsulation layer 50 is configured to encapsulate the single sub-pixel 20, so as to avoid interference between adjacent sub-pixels 20. The protective layer 60 is configured to encapsulate the entire display panel 100, which further seals and protects the display panel 100, thereby increasing the service life of the entire display panel 100 and avoid pollution from the external environment.

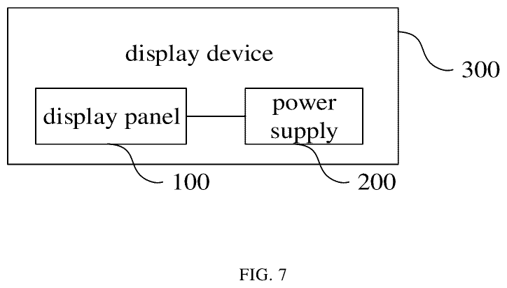

To solve the above problems, the present disclosure further provides a display device 300, as illustrated in FIG. 7, FIG. 7 is a structural schematic view of a display device in some embodiments of the present disclosure. The display device 300 includes the display panel 100 and a power supply 200, and the display panel 100 is connected to the power supply 200. The display panel 100 is the display panel 100 in any one of the above embodiments, or manufactured by the above manufacturing method. The power supply 200 supplies power to the display panel 100, so that a stable picture output is provided to the display device 300 through the display panel 100.

In the present disclosure, the display panel 100 includes the substrate 10, the plurality of sub-pixels 20, the plurality of pixel defining layers 30, the plurality of isolation structures 40, and the encapsulation layer 50. The plurality of sub-pixels 20 are disposed on the substrate 10. The plurality of pixel defining layers 30 are disposed on the substrate 10 and configured to define positions of the plurality of sub-pixels 20. Each isolation structure 40 includes the main body 41 and the overhang 42, and the main body 41 is disposed on the surface of the corresponding pixel defining layer 30 away from the substrate 10. The overhang 42 is disposed on the surface of the main body 41 away from the corresponding pixel defining layer 30. The encapsulation layer 50 is disposed on the surface of each sub-pixel 20 away from the substrate 10. The parts of the encapsulation layer 50 are disposed on the side of the overhang 42 away from the main body 41. The encapsulation layer 50 includes the edges B, each edge B is disposed on the side of the overhang 42 away from the main body 41, and each edge B is close to the sub-pixel 20 adjacent to the encapsulation layer 50. Each edge B and the overhang 42 define the gap space A. That is, gap spaces A are formed between the overhang 42 and the encapsulation layer 50. The width of the gap space A along the set direction is less than or equal to 4 μm, and the set direction is the direction parallel to the line connecting two sub-pixels 20 adjacent to the overhang 42.

During making the display panel 100, the process flow is added, so that some structures of the display panel 100 are removed, so as to reduce or eliminate the gap space A of the undercut structure, thereby eliminating the impact on the subsequent encapsulating process. Moreover, the dense protective layer 60 is disposed on the corresponding encapsulation layer 50 and the overhang 42, thereby further improving sealing of the display panel 100, and effectively improving the reliability and the service life of the display panel 100.

By above method, the width of each gap space between the overhang and the encapsulation layer along the set direction is less than or equal to 4 μm. Since a size of each gap space reduces, during the etching process of the encapsulation layer, residual water vapor (such as etching liquid) or other impurities reduce, thereby improving the reliability of the display panel. Moreover, the protective layer is disposed on the overhang, thereby further improving sealing and service life of the display panel.

The embodiments of the present disclosure are described in detail, and specific examples are provided to describe and explain the principles and implementation modes of the present disclosure. The above explanation of the examples is only used to help understand the methods and core ideas of the present disclosure. Furthermore, according to the ideas of the present disclosure, those of ordinary skill in the art may change the specific implementation mode and the application scope. In summary, the contents of the present specification should not be understood as limiting the present disclosure.

What is claimed is:

1. A display panel, comprising:
a substrate;
a plurality of sub-pixels, disposed on the substrate;
a plurality of pixel limiting layers, disposed on the substrate and configured to limit positions of the plurality of subpixels;
a plurality of isolation structures, wherein each of the plurality of isolation structures comprises a main body and an overhang, the main body is disposed on a surface of a corresponding one of the plurality of pixel defining layers away from the substrate, and the overhang is disposed on a surface of the main body away from the corresponding one of the plurality of pixel defining layers;
an encapsulation layer, disposed a surface of each of the plurality of sub-pixels away from the substrate, wherein in response to parts of the encapsulation layer being disposed on a side of the overhang away from the main body, the parts of the encapsulation layer and the overhang define gap spaces; a width of each gap space along a set direction is less than or equal to 4 μm, and the set direction is a direction parallel to a line connecting two sub-pixels adjacent to the overhang; and
a protective layer, disposed on a side of the encapsulation layer away from the substrate and the side of the overhang away from the substrate.

2. The display panel according to claim 1, wherein each of the plurality of sub-pixels comprises an anode layer, a first light-emitting layer, and a cathode layer stacked in sequence;
the display panel further comprises a second light-emitting layer, the second light-emitting layer is disposed on a surface of the overhang away from the main body, and the second light-emitting layer is close to an edge of the overhang; and
the parts of the encapsulation layer are disposed on a surface of the second light-emitting layer away from the overhang, and the parts of the encapsulation layer extend out of the second light-emitting layer toward another adjacent sub-pixel, so that the gap spaces are formed between the overhang, the second light-emitting layer, and the encapsulation layer.

3. The display panel according to claim 2, wherein the first light-emitting layer and the second light-emitting layer are formed by the same deposition process.

4. The display panel according to claim 1, wherein the encapsulation layer is not disposed on the side of the overhang away from the main body.

5. The display panel according to claim 4, wherein a surface of the encapsulation layer away from the substrate is flush with a surface of the overhang away from the main body.

6. A method for making a display panel, comprising:
providing a substrate;
forming a plurality of anode layers on the substrate;
forming a plurality of pixel defining layers, a plurality of main bodies, and a plurality of overhangs in sequence on the substrate, wherein the plurality of pixel defining layers are configured to define positions of a plurality of sub-pixels, and the plurality of main bodies and the plurality of overhangs form a plurality of isolation structures;
forming a first light emitting layer on a surface of each anode layer away from the substrate;
forming a cathode layer on a surface of the first light emitting layer away from a corresponding one of the plurality of anode layers;
forming an encapsulation layer on a surface of the cathode layer away from the substrate, wherein in response to parts of the encapsulation layer being disposed on a side of the overhang away from the main body, the parts of the encapsulation layer and the overhang define gap spaces;
removing a part of the encapsulation layer, so that a width of each gap space along a set direction is less than or equal to 4 μm, wherein the set direction is a direction parallel to a line connecting two sub-pixels adjacent to the overhang; and
forming a protection layer on a surface of the encapsulation layer away from the substrate and a surface of the overhang away from the substrate.

7. The method for making the display panel according to claim 6, wherein
the forming a first light emitting layer on a surface of each anode layer away from the substrate, comprises:
forming the first light emitting layer on the surface of each anode layer away from the substrate and forming second light-emitting layers on the surface of the overhang away from the main body;
the forming an encapsulation layer on a surface of the cathode layer away from the substrate, wherein in response to parts of the encapsulation layer being disposed on a side of the overhang away from the main body, the parts of the encapsulation layer and the overhang define gap spaces, comprises:
forming the encapsulation layer on the surface of the cathode layer away from the substrate, wherein the parts of the encapsulation layer are disposed the surface of the second light-emitting layer away from the overhang and extends out of the second light-emitting layer toward another adjacent sub-pixel, so that the gap space is formed between the overhang, each second light-emitting layer, and the encapsulation layer.

8. The method for making the display panel according to claim 7, wherein the removing a part of the encapsulation layer, so that a width of each gap space along a set direction is less than or equal to 4 μm, comprises:
removing the parts of the encapsulation layer, and removing the second light-emitting layers, so that the encapsulation layer and the second light-emitting layers do not exist on the side of the overhang away from the main body.

9. The method for making the display panel according to claim 8, wherein after removing the parts of the encapsulation layer and removing the second light-emitting layers, the method further comprises:
flattening the encapsulation layer.

10. A display device, comprising:
a display panel, comprising:
a substrate;
a plurality of sub-pixels, disposed on the substrate;
a plurality of pixel limiting layers, disposed on the substrate and configured to limit positions of the plurality of subpixels;
a plurality of isolation structures, wherein each of the plurality of isolation structures comprises a main body and an overhang, the main body is disposed on a surface of a corresponding one of the plurality of pixel defining layers away from the substrate, and the overhang is disposed on a surface of the main body away from the corresponding one of the plurality of pixel defining layers;
an encapsulation layer, disposed a surface of each of the plurality of sub-pixels away from the substrate, wherein in response to parts of the encapsulation layer being disposed on a side of the overhang away from the main body, the parts of the encapsulation layer and the overhang define gap spaces; a width of each gap space along a set direction is less than or equal to 4 μm, and the set direction is a direction parallel to a line connecting two sub-pixels adjacent to the overhang; and
a protective layer, disposed on a side of the encapsulation layer away from the substrate and the side of the overhang away from the substrate; and
a power supply, configured for supplying power to the display panel.

11. The display device according to claim 10, wherein each of the plurality of sub-pixels comprises an anode layer, a first light-emitting layer, and a cathode layer stacked in sequence;
the display panel further comprises a second light-emitting layer, the second light-emitting layer is disposed on a surface of the overhang away from the main body, and the second light-emitting layer is close to an edge of the overhang; and
the parts of the encapsulation layer are disposed on a surface of the second light-emitting layer away from the overhang, and the parts of the encapsulation layer extend out of the second light-emitting layer toward another adjacent sub-pixel, so that the gap spaces are formed between the overhang, the second light-emitting layer, and the encapsulation layer.

12. The display device according to claim 11, wherein the first light-emitting layer and the second light-emitting layer are formed by the same deposition process.

13. The display device according to claim 10, wherein the encapsulation layer is not disposed on the side of the overhang away from the main body.

14. The display device according to claim 13, wherein a surface of the encapsulation layer away from the substrate is flush with a surface of the overhang away from the main body.

15. The display device according to claim 10, wherein the display panel is formed by using a method, and the method comprises:
providing the substrate;
forming the plurality of anode layers on the substrate;
forming the plurality of pixel defining layers, a plurality of main bodies, and a plurality of overhangs in sequence on the substrate, wherein the plurality of pixel defining layers are configured to define positions of the plurality of sub-pixels, and the plurality of main bodies and the plurality of overhangs form the plurality of isolation structures;
forming a first light emitting layer on a surface of each anode layer away from the substrate;
forming a cathode layer on a surface of the first light emitting layer away from a corresponding one of the plurality of anode layers;
forming the encapsulation layer on a surface of the cathode layer away from the substrate, wherein in response to parts of the encapsulation layer being disposed on the side of the overhang away from the main body, the parts of the encapsulation layer and the overhang define gap spaces;
removing a part of the encapsulation layer, so that the width of each gap space along the set direction is less than or equal to 4 μm; and
forming the protection layer on the surface of the encapsulation layer away from the substrate and the surface of the overhang away from the substrate.

16. The display device according to claim 15, wherein
the forming a first light emitting layer on a surface of each anode layer away from the substrate, comprises:
forming the first light emitting layer on the surface of each anode layer away from the substrate and forming second light-emitting layers on the surface of the overhang away from the main body;
the forming an encapsulation layer on a surface of the cathode layer away from the substrate, wherein in response to parts of the encapsulation layer being disposed on a side of the overhang away from the main body, the parts of the encapsulation layer and the overhang define gap spaces, comprises:
forming the encapsulation layer on the surface of the cathode layer away from the substrate, wherein the parts of the encapsulation layer are disposed the surface of the second light-emitting layer away from the overhang and extends out of the second light-emitting layer toward another adjacent sub-pixel, so that the gap space is formed between the overhang, each second light-emitting layer, and the encapsulation layer.

17. The display device according to claim 16, wherein the removing a part of the encapsulation layer, so that a width of each gap space along a set direction is less than or equal to 4 μm, comprises:
removing the parts of the encapsulation layer, and removing the second light-emitting layers, so that the encapsulation layer and the second light-emitting layers do not exist on the side of the overhang away from the main body.

18. The display device according to claim 17, wherein after removing the parts of the encapsulation layer and removing the second light-emitting layers, the method further comprises:
flattening the encapsulation layer.
